(19) United States
(12) Patent Application Publication
(10) Pub. No.: US 2025/0385229 A1
(43) Pub. Date: Dec. 18, 2025

(54) STACKED STRUCTURE, SEMICONDUCTOR DEVICE, AND METHOD FOR MANUFACTURING SEMICONDUCTOR DEVICE

(71) Applicant: Kioxia Corporation, Tokyo (JP)

(72) Inventor: Satoshi HONGOU, Yokkaichi Mie (JP)

(21) Appl. No.: 19/064,584

(22) Filed: Feb. 26, 2025

(30) Foreign Application Priority Data
Jun. 14, 2024 (JP) 2024-096773

(51) Int. Cl. H01L 25/16; H01L 23/00; H10B 41/27; H10B 41/50; H10B 43/27; H10B 43/50; H10B 80/00; H10D 80/30

(52) U.S. Cl. CPC H01L 25/16; H01L 23/562; H01L 24/80; H10B 41/50; H10B 43/50; H10B 80/00; H10D 80/30; H01L 24/08; H01L 2224/08145; H01L 2224/80895; H01L 2224/80896; H01L 2924/1431; H10B 41/27; H10B 43/27

(57) ABSTRACT

A stacked structure for a semiconductor device includes a first wafer including a first substrate and a first semiconductor element on the first substrate and having first and second surfaces between which the first substrate and the first semiconductor element are disposed, a second wafer including a second substrate and a second semiconductor element on the second substrate and having first and second surfaces between which the second substrate and the second semiconductor element are disposed, and a third wafer including a third substrate and a third semiconductor element on the third substrate and having first and second surfaces between which the third substrate and the third semiconductor element are disposed. The second and third semiconductor elements are of a same type.

### CROSS-REFERENCE TO RELATED APPLICATION(S)

This application is based upon and claims the benefit of priority from Japanese Patent Application No. 2024-096773, filed Jun. 14, 2024, the entire contents of which are incorporated herein by reference.

### FIELD

Embodiments described herein relate generally to a stacked structure, a semiconductor device, and a method for manufacturing a semiconductor device.

### BACKGROUND

Warpage of a stacked body including a plurality of stacked wafers may increase when the number of stacked wafers is increased.

### BRIEF DESCRIPTION OF THE DRAWINGS

FIG. 1 is a diagram illustrating a configuration of a stacked structure according to a first embodiment.

FIG. 2A is a cross-sectional view illustrating a configuration of the stacked structure according to the first embodiment.

FIG. 2B is a cross-sectional view illustrating a configuration of the stacked structure according to the first embodiment.

FIG. 3A is a diagram illustrating a method for manufacturing the stacked structure according to the first embodiment.

FIG. 3B is a diagram illustrating the method for manufacturing the stacked structure, subsequent to FIG. 3A.

FIG. 3C is a diagram illustrating the method for manufacturing the stacked structure, subsequent to FIG. 3B.

FIG. 3D is a diagram illustrating the method for manufacturing the stacked structure, subsequent to FIG. 3C.

FIG. 3E is a diagram illustrating the method for manufacturing the stacked structure, subsequent to FIG. 3D.

FIG. 4 is a diagram illustrating a configuration of a stacked structure according to a comparative example.

FIG. 5 is a cross-sectional view illustrating a configuration of the stacked structure according to the comparative example.

FIG. 6A is a diagram illustrating a method for manufacturing the stacked structure according to the comparative example.

FIG. 6B is a diagram illustrating the method for manufacturing the stacked structure, subsequent to FIG. 3A.

FIG. 6C is a diagram illustrating the method for manufacturing the stacked structure, subsequent to FIG. 3B.

FIG. 7 is a diagram illustrating a configuration of a stacked structure according to a second embodiment.

FIG. 8 is a diagram illustrating a configuration of a stacked structure according to a third embodiment.

FIG. 9 is a diagram illustrating a configuration of a stacked structure according to a fourth embodiment.

FIG. 10 is a diagram illustrating a configuration of a stacked structure according to a fifth embodiment.

FIG. 11 is a diagram illustrating a configuration of a stacked structure according to a sixth embodiment.

### DETAILED DESCRIPTION

Embodiments provide a stacked structure, a semiconductor device, and a method for manufacturing a semiconductor device that can prevent warpage.

In general, according to one embodiment, a stacked structure for a semiconductor device, comprises: a first wafer including a first substrate and a first semiconductor element on the first substrate and having first and second surfaces between which the first substrate and the first semiconductor element are disposed; a second wafer including a second substrate and a second semiconductor element on the second substrate and having first and second surfaces between which the second substrate and the second semiconductor element are disposed, wherein the second substrate extends along the first surface of the second wafer, and the second wafer is attached to a first surface side of the first wafer such that the second surface of the second wafer is closer to the first surface of the first wafer than the first surface of the second wafer; and a third wafer including a third substrate and a third semiconductor element on the third substrate and having first and second surfaces between which the third substrate and the third semiconductor element are disposed, wherein the third substrate extends along the first surface of the third wafer, and the third wafer is attached to a second surface side of the first wafer such that the second surface of the third wafer is closer to the second surface of the second wafer than the first surface of the third wafer. The second and third semiconductor elements are of a same type.

Embodiments will be described below with reference to the accompanying drawings. Embodiments of this disclosure will not limit to the ones described below. In the specification and the drawings, the same components as those already described with respect to preceding drawings are denoted by the same reference signs, and the detailed descriptions thereof are appropriately omitted.

### First Embodiment

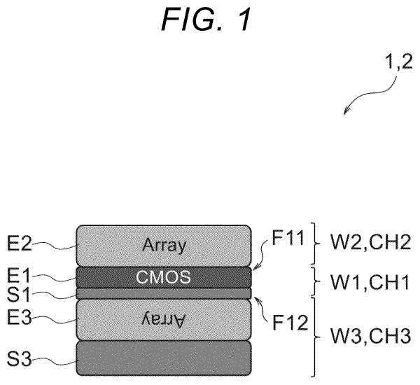

FIG. 1 is a diagram illustrating a configuration of a stacked structure 1 according to a first embodiment. FIG. 1 also illustrates one semiconductor device 2 after the stacked structure 1 is divided into a plurality of semiconductor devices 2.

The stacked structure 1 includes three stacked wafers W1, W2, W3.

The wafer W1 is, for example, a logic wafer. The wafer W1 includes a surface F11 and a surface F12 opposite to the surface F11. The wafer W1 includes a semiconductor element E1 and a semiconductor substrate S1 on which the semiconductor element E1 is provided. In the example illustrated in FIG. 1, the semiconductor element E1 is provided on the surface F11 side. The semiconductor substrate S1 is provided on the surface F12 side. The semiconductor element E1 is, for example, a read circuit. In the example illustrated in FIG. 1, the semiconductor element E1 of the wafer W1 is, for example, a controller that controls a memory cell array to be described below. The controller is, for example, a Complementary Metal Oxide Semiconductor (CMOS) circuit.

The wafer W2 is, for example, a memory array wafer. The wafer W2 is provided on one surface (e.g., the surface F11) side of the wafer W1. The wafer W2 includes a semiconductor element E2 and a semiconductor substrate S2 on which the semiconductor element E2 is provided. It should be noted that the semiconductor substrate S2 is not necessarily provided as in the example illustrated in FIG. 1. The semiconductor element E2 is, for example, a memory element. In the example illustrated in FIG. 1, the semiconductor element E2 of the wafer W2 is, for example, a memory cell array. The memory cell array may be a three-dimensional memory cell array in which a plurality of memory cells is disposed three-dimensionally. The memory cell array is, for example, a three-dimensional NAND memory, but may be a Dynamic Random Access Memory (DRAM) array or the like.

The wafer W3 is, for example, a memory array wafer. The wafer W3 is provided on the other surface (e.g., the surface F12) side of the wafer W1. The wafer W3 includes a semiconductor element E3 and a semiconductor substrate S3 on which the semiconductor element E3 is provided. The semiconductor element E3 is, for example, a memory element. In the example illustrated in FIG. 1, the semiconductor element E3 of the wafer W3 is, for example, a memory cell array. The memory cell array may be a three-dimensional memory cell array in which a plurality of memory cells is disposed three-dimensionally. The memory cell array is, for example, a three-dimensional NAND memory, but may be a Dynamic Random Access Memory (DRAM) array or the like.

The wafers W2, W3 are wafers of the same type. That is, the semiconductor elements E2, E3 are elements of the same type.

Some semiconductor elements such as a semiconductor element including a transistor may need a semiconductor substrate to have a certain thickness for a semiconductor operation. The semiconductor substrate S1 has a thickness corresponding to an operating limit of the semiconductor element E1 which is a CMOS circuit. The semiconductor substrate S1 has a thickness of 5 μm or more, for example. The thickness of the first semiconductor substrate S1 may be smaller than the thickness of one or both of the second semiconductor substrate S2 and the third semiconductor substrate S3.

The semiconductor device 2 includes three stacked chips CH1, CH2, CH3.

The chip CH1 is, for example, a logic chip. The chip CH1 is one chip after the wafer W1 in the stacked structure 1 is divided into a plurality of chips. The chip CH1 includes the semiconductor element E1 and the semiconductor substrate S1.

The chip CH2 is, for example, a memory chip. The chip CH2 is one chip after the wafer W2 in the stacked structure 1 is divided into a plurality of chips. The chip CH2 includes the semiconductor element E2 and the semiconductor substrate S2.

The chip CH3 is, for example, a memory chip. The chip CH3 is one chip after the wafer W3 in the stacked structure 1 is divided into a plurality of chips. The chip CH3 includes the semiconductor element E3 and the semiconductor substrate S3.

The chips CH2, CH3 are chips of the same type.

Here, the wafers W1, W2, W3 may have warpage. The warpage of a wafer is caused, for example, by a difference in thermal expansion coefficient between a material (e.g., silicon (Si)) of a semiconductor substrate and a material of a stacked film (i.e., a semiconductor element) formed at a film forming temperature of several hundred degrees C.

Then, the wafer W2 and the wafer W3 are disposed with the wafer W1 interposed therebetween. More specifically, the wafer W2 and the wafer W3 face each other with the wafer W1 interposed therebetween. That is, the wafers W2, W3 are disposed upside down with respect to each other. In the example illustrated in FIG. 1, the descriptions of “Array” in the semiconductor elements E2, E3 are inverted with respect to each other.

The warpage of the wafers W2, W3 can be canceled by placing the wafers W2, W3 of the same type with the wafer W1 interposed therebetween. As a result, the warpage of the stacked structure 1 and the semiconductor device 2 can be prevented.

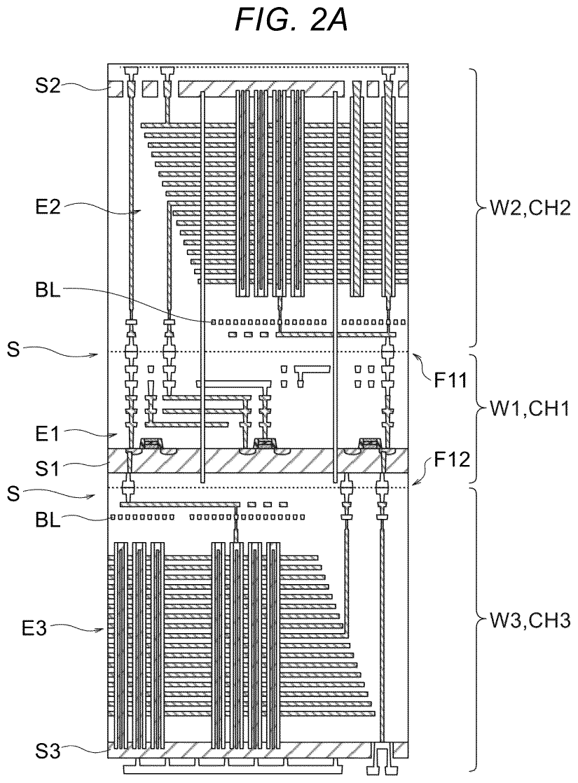

FIG. 2A and FIG. 2B are cross-sectional views illustrating a configuration of the stacked structure 1 according to the first embodiment. FIG. 2A and FIG. 2B are cross-sectional views of the stacked structure 1 illustrated in FIG. 1.

The wafer W1 and the wafer W2 are stuck together on a sticking surface S. Similarly, the wafer W1 and the wafer W3 are stuck together on the sticking surface S.

The semiconductor element E1 includes, for example, a transistor provided on the semiconductor substrate S1.

The semiconductor element E2 includes, for example, a memory cell array. A bit line BL of the semiconductor element E2 is provided on the lower surface side of the wafer W2, that is, on the wafer W1 side of the wafer W2.

The semiconductor element E3 includes, for example, a memory cell array. A bit line BL of the semiconductor element E3 is provided on the upper surface side of the wafer W3, that is, on the wafer W1 side of the wafer W3. A through electrode pad penetrating the semiconductor substrate S1 and an electrode pad formed on a surface of the semiconductor element E3 (i.e., the upper surface of the wafer W3) are directly joined or stuck together. An electrode pad formed on a surface (i.e., the upper surface of the wafer W1) of the semiconductor element E1 and an electrode pad formed on a surface of the semiconductor element E2 (i.e., the lower surface of the wafer W2) are directly joined. The semiconductor element E2 and the semiconductor element E3 may be directly electrically connected to each other without interposition of the transistor of the semiconductor element E1.

Thus, the wafer W2 and the wafer W3 are disposed upside down with respect to each other as illustrated in FIG. 2A and FIG. 2B. A pad to be connected to the outside is formed on the wafer W3 side, for example. At this time, the semiconductor substrate S3 may be at least partially or wholly removed. Alternatively, a pad to be connected to the outside may be formed on the wafer W2 side. At this time, the semiconductor substrate S2 may be at least partially or wholly removed. The semiconductor substrate is removed by polishing, grinding, etching, or the like.

It should be noted that the semiconductor substrate S2 of the wafer W2 is illustrated in FIG. 2A, but the semiconductor substrate S2 is not necessarily provided as illustrated in FIG. 1.

The step-like portion of the memory cell array in the semiconductor element E2 is formed to ascend the steps from the upper left to the lower right in FIG. 2A. The step-like portion of the memory cell array in the semiconductor element E3 is formed to ascend the steps from the lower right to the upper left in FIG. 2A. That is, the step-like portion of the memory cell array in the semiconductor element E2 and the step-like portion of the memory cell array in the semiconductor element E3 have a point symmetric relationship.

The step-like portion of the memory cell array in the semiconductor element E2 is formed to ascend the steps from the upper left to the lower right in FIG. 2B. The step-like portion of the memory cell array in the semiconductor element E3 is formed to ascend the steps from the lower left to the upper right in FIG. 2B. That is, the step-like portion of the memory cell array in the semiconductor element E2 and the step-like portion of the memory cell array in the semiconductor element E3 have a line symmetric relationship.

Next, a method for manufacturing the stacked structure 1 will be described.

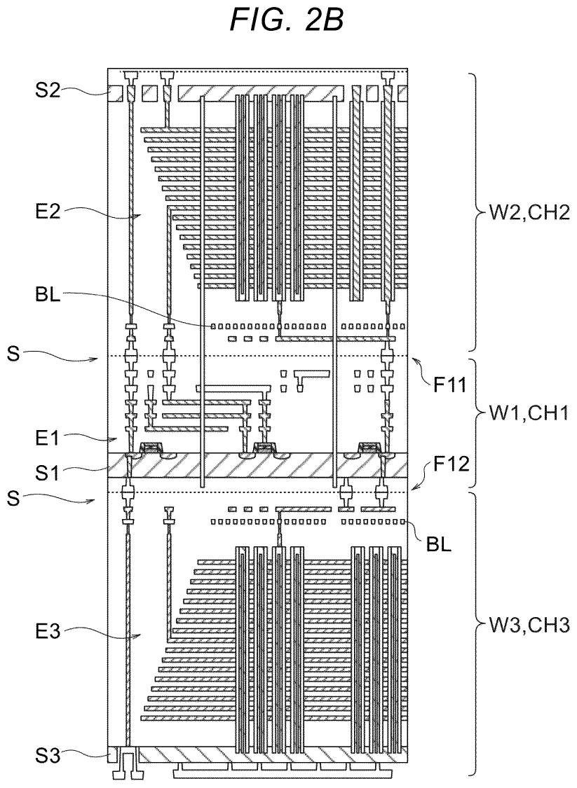

FIG. 3A to FIG. 3E are diagrams illustrating a method for manufacturing the stacked structure 1 according to the first embodiment.

First, the wafer W1 and the wafer W2 are prepared as illustrated in FIG. 3A. The wafers W1, W2 include the semiconductor substrates S1, S2, respectively. Since the semiconductor elements E1, E2 are thin films, it is difficult to carry the respective semiconductor elements E1, E2 in a state where the semiconductor substrates S1, S2 are not provided. The semiconductor substrates S1, S2 supporting the semiconductor elements E1, E2 facilitate the handling of the wafers W1, W2.

Each of the wafers W1, W2 illustrated in FIG. 3A has convex warpage. More specifically, the wafer W1 which is a logic wafer has warpage of a convex a. The wafer W2 which is a memory array wafer has warpage of a convex b. That is, the amounts of the warpage of the wafers W1, W2 are different from each other. The degrees of warpage satisfies the convex a<the convex b.

Next, the wafer W1 and the wafer W2 are stuck together as illustrated in FIG. 3B. A surface on the semiconductor element E1 side of the wafer W1 and a surface on the semiconductor element E2 side of the wafer W2 are stuck together.

Next, as illustrated in FIG. 3C, the stacked structure of the wafers W1, W2 is placed upside down, and thinned by removing at least part the semiconductor substrate S1. The wafer W3 illustrated in FIG. 3C is prepared at the same timing as the wafer W2 in the step illustrated in FIG. 3A, for example. The semiconductor substrate S1 may be wholly removed. Removal is performed by polishing, grinding, etching, or the like.

The stacked structure of the wafers W1, W2 illustrated in FIG. 3C has convex warpage. More specifically, the stacked structure of the wafers W1, W2 has warpage due to a concave a, which is the inversion of the convex a, and the convex b. Because of the convex a<the convex b as described above, the stacked structure of the wafers W1, W2 has convex warpage.

Next, the stacked structure of the wafers W1, W2 and the wafer W3 are stuck together as illustrated in FIG. 3D. A surface on the semiconductor substrate S1 side of the wafer W1 and a surface on the semiconductor element E3 side of the wafer W3 are stuck together.

Next, as illustrated in FIG. 3E, the wafers W1, W2, W3 are placed upside down, and the semiconductor substrate S2 is thinned. In the example illustrated in FIG. 3E, the semiconductor substrate S2 is removed. As a result, the stacked structure 1 illustrated in FIG. 1 is completed.

Since the semiconductor substrates S1, S3 are left even after the semiconductor substrate S2 is removed, the stacked structure of the wafers W1, W2, W3 remains easy to handle. Thus, the thickness of the second semiconductor substrate S2 may differ from the thickness of the third semiconductor substrate S3. In the example illustrated in FIG. 3E, the thickness of the second semiconductor substrate S2 is 0 μm.

The stacked structure of the wafers W1, W2, W3 illustrated in FIG. 3E has convex warpage. More specifically, the stacked structure of the wafers W1, W2, W3 has warpage due to the convex a, a concave b, which is the inversion of the convex b, and the convex b. Since the concave b and the convex b cancel out each other, the stacked structure of the wafers W1, W2, W3 has warpage of the convex a.

Thereafter, the semiconductor device 2 is completed by dividing the stacked structure 1. It should be noted that the semiconductor substrate S3 may be removed before completion of the semiconductor device 2. A pad to be connected to the outside may be formed after removing the semiconductor substrate S3, or may be formed on the semiconductor substrate S3 without removing the semiconductor substrate S3. The pad to be connected to the outside may be formed on the semiconductor substrate S2 side.

As described above, according to the first embodiment, the wafer W2 and the wafer W3 are disposed with the wafer W1 interposed therebetween. Accordingly, the warpage of the wafers W2, W3 can be canceled. As a result, the warpage of the stacked structure 1 and the semiconductor device 2 can be prevented.

The warpage of any semiconductor substrate may affect the warpage of the stacked structure 1 and the semiconductor device 2. When the warpage of the wafer W2, W3 is canceled to be negligible, the warpage of the stacked structure 1 is substantially caused by the warpage of the wafer W1. The warpage of a wafer depends on stress and thickness. In the example illustrated in FIG. 3E, the semiconductor element E1 has upward convex warpage, the semiconductor substrate S1 has downward convex warpage, and the wafer W1 has upward convex warpage of the convex a as a whole. The downward convex warpage of the semiconductor substrate S1 increases as the thickness of the semiconductor substrate S1 increases. Thus, the thickness of the semiconductor substrate S1 may be adjusted such that the warpage of the semiconductor element E1 and the semiconductor substrate S1 are balanced out. As a result, the warpage of the stacked structure 1 and the semiconductor device 2 can be further prevented.

For example, when each of the semiconductor elements E2, E3 has a vertically symmetrical internal structure, the warpage of each of the wafers W2, W3 does not change even when the wafers W2, W3 are inverted upside down. In this case, the wafers W2, W3 may be disposed without facing each other. That is, the wafers W2, W3 may be disposed in the same orientation without being inverted with respect to each other.

### COMPARATIVE EXAMPLE

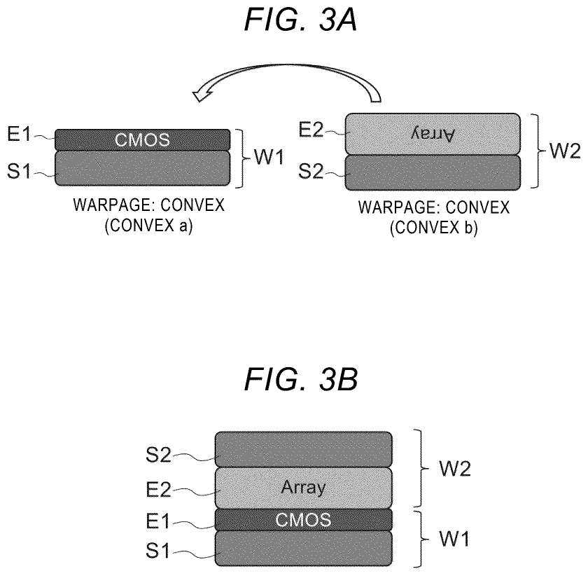

FIG. 4 is a diagram illustrating a configuration of a stacked structure 1a according to a comparative example. In the comparative example, the arrangement of stacked wafers differs from that of the first embodiment. In FIG. 4, some semiconductor substrates are omitted.

The stacked structure 1a includes three stacked wafers W1a, W2a, W3a. The wafer W1a is, for example, a logic wafer. The wafer W2a, W3a are, for example, memory array wafers.

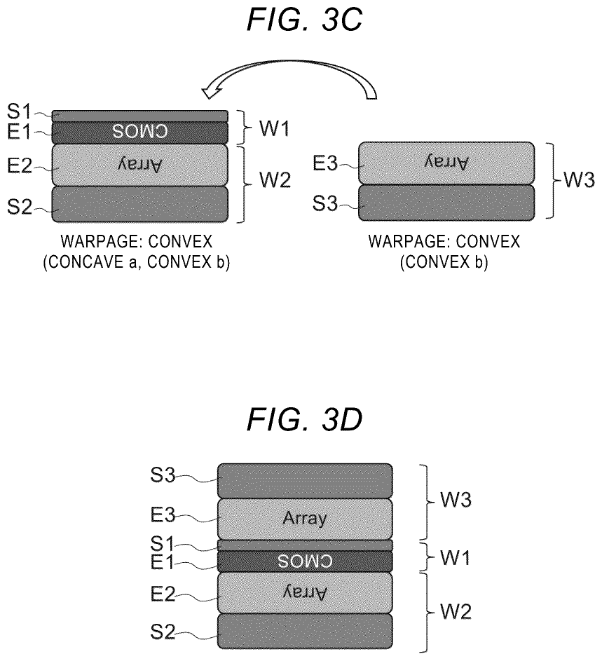

FIG. 5 is a cross-sectional view illustrating a configuration of the stacked structure 1a according to the comparative example. FIG. 5 is a cross-sectional view of the stacked structure 1a illustrated in FIG. 4.

The wafer W1a and the wafer W3a disposed with the wafer W2a interposed therebetween are wafers of different types. The wafers W2a, W3a are disposed in the same orientation with respect to each other.

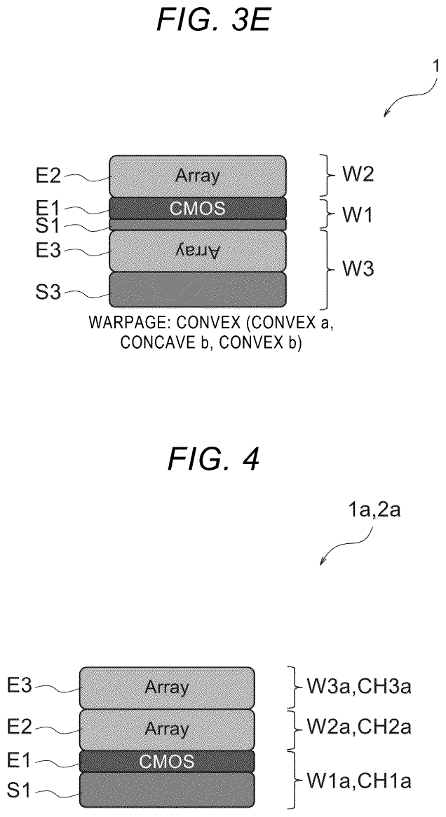

FIG. 6A to FIG. 6C are diagrams illustrating a method for manufacturing the stacked structure 1a according to the comparative example. The steps illustrated in FIG. 6A to FIG. 6C are performed after steps similar to the steps illustrated in FIG. 3A and FIG. 3B. It should be noted that the wafers W1, W2 illustrated in FIG. 3A and FIG. 3B are the same as the wafers W1a, W2a.

After the wafer W1a and the wafer W2a are stuck together (see FIG. 3B), the semiconductor substrate S2 is thinned as illustrated in FIG. 6A. In the example illustrated in FIG. 6A, the semiconductor substrate S2 is removed. The wafer W3a illustrated in FIG. 6A is prepared at the same timing as the wafer W2a in the step illustrated in FIG. 3A, for example.

The stacked structure of the wafers W1a, W2a illustrated in FIG. 6A has concave warpage. More specifically, the stacked structure of the wafers W1a, W2a has warpage due to the convex a and a concave b which is the inversion of the convex b. Because of the convex a<the convex b as described above, the stacked structure of the wafers W1a, W2a has concave warpage.

Next, the stacked structure of the wafers W1a, W2a and the wafer W3a are stuck together as illustrated in FIG. 6B.

Next, the semiconductor substrate S3 is thinned as illustrated in FIG. 6C. In the example illustrated in FIG. 6C, the semiconductor substrate S3 is removed.

The stacked structure of the wafers W1a, W2a, W3a illustrated in FIG. 6C has concave warpage. More specifically, the stacked structure of the wafers W1a, W2a, W3a has warpage due to the convex a and two concaves b which are the inversion of two convexes b. Because of the convex a<the convex b as described above, the stacked structure of the wafers W1a, W2a, W3a has concave warpage.

In the step illustrated in FIG. 6C, the concave warpage increases because the warpage of the two concaves b due to the wafers W2a, W3a, which are memory array wafers, is superimposed. As a result, the warpage of the stacked structure 1a increases.

Meanwhile, according to the first embodiment, the wafers W2, W3 of the same type are disposed with the wafer W1 interposed therebetween. Accordingly, the warpage of the wafers W2, W3 can be canceled. As a result, the warpage of the stacked structure 1 and the semiconductor device 2 can be prevented.

### Second Embodiment

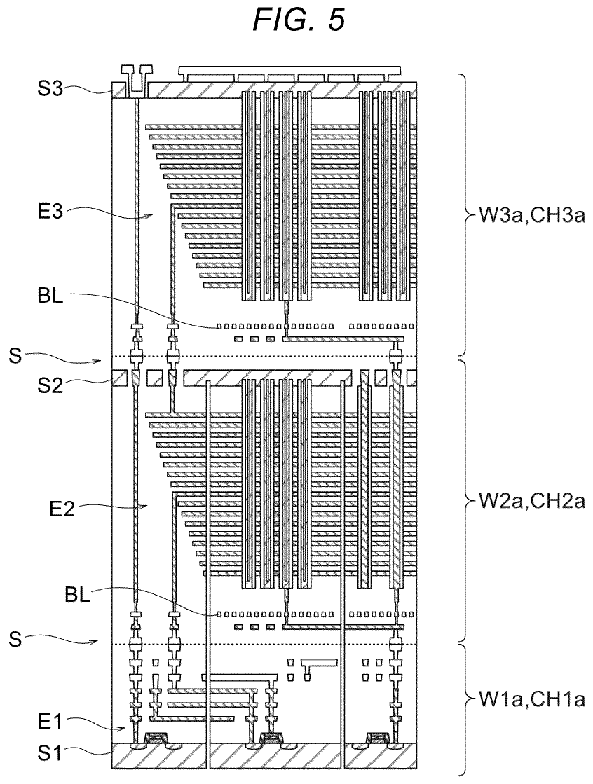

FIG. 7 is a diagram illustrating a configuration of a stacked structure 1 according to a second embodiment. The second embodiment differs from the first embodiment in that the wafers W2, W3 are inverted upside down. In FIG. 7, the semiconductor substrates are omitted.

Both the wafers W2, W3 are inverted upside down as compared to FIG. 1 of the first embodiment. Also in this case, the wafers W2, W3 face each other with the wafer W1 interposed therebetween. Accordingly, the warpage of the wafers W2, W3 can be canceled.

Detailed description of the semiconductor device 2 including the chips CH1, CH2, CH3 obtained by dividing the wafers W1, W2, W3 is omitted.

As in the second embodiment, the wafers W2, W3 may be inverted upside down. The stacked structure 1 of the second embodiment can achieve an effect similar to that of the first embodiment.

### Third Embodiment

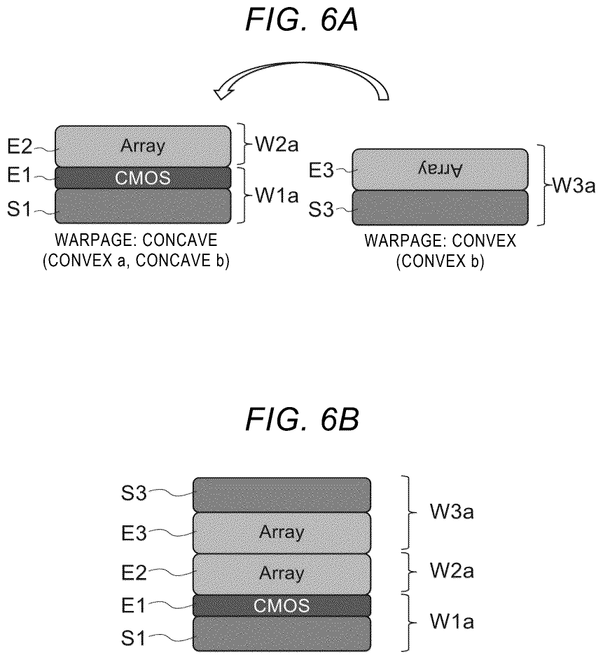

FIG. 8 is a diagram illustrating a configuration of a stacked structure 1 according to a third embodiment. The third embodiment differs from the first embodiment in that the wafer W1 is inverted upside down. In FIG. 8, the semiconductor substrates S1, S2, S3 are omitted.

The wafer W1 is inverted upside down as compared to FIG. 1 of the first embodiment. Also in this case, the wafers W2, W3 face each other with the wafer W1 interposed therebetween. Accordingly, the warpage of the wafers W2, W3 can be canceled.

Detailed description of the semiconductor device 2 including the chips CH1, CH2, CH3 obtained by dividing the wafers W1, W2, W3 is omitted.

As in the third embodiment, the wafer W1 may be inverted upside down. The stacked structure 1 of the third embodiment can achieve an effect similar to that of the first embodiment.

### Fourth Embodiment

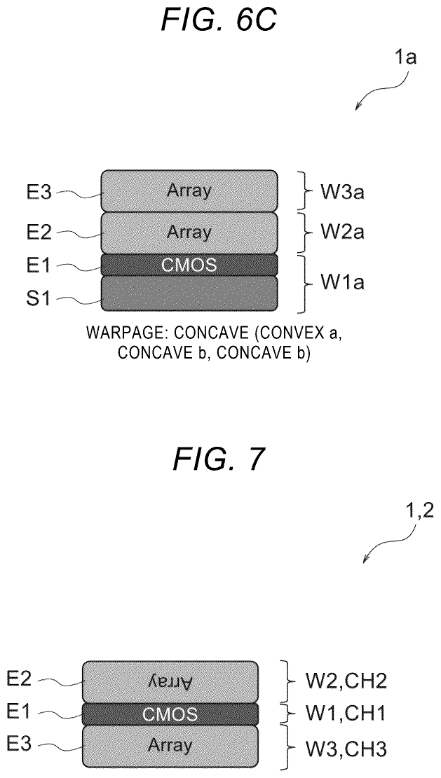

FIG. 9 is a diagram illustrating a configuration of a stacked structure 1 according to a fourth embodiment. The fourth embodiment differs from the first embodiment in that two logic wafers are disposed with a memory array wafer interposed therebetween. In FIG. 9, the semiconductor substrates are omitted.

The wafer W1 is, for example, a memory array wafer. The wafers W2, W3 are, for example, logic wafers.

Also in this case, the wafers W2, W3 face each other with the wafer W1 interposed therebetween. Accordingly, the warpage of the wafers W2, W3 can be canceled.

Detailed description of the semiconductor device 2 including the chips CH1, CH2, CH3 obtained by dividing the wafers W1, W2, W3 is omitted.

As in the fourth embodiment, two logic wafers may be disposed with a memory array wafer interposed therebetween. The stacked structure 1 of the fourth embodiment can achieve an effect similar to that of the first embodiment. The stacked structure 1 according to the fourth embodiment may be combined with at least one of the second embodiment or the third embodiment. That is, both the wafers W2, W3 may be inverted upside down, or the wafer W1 may be inverted upside down.

### Fifth Embodiment

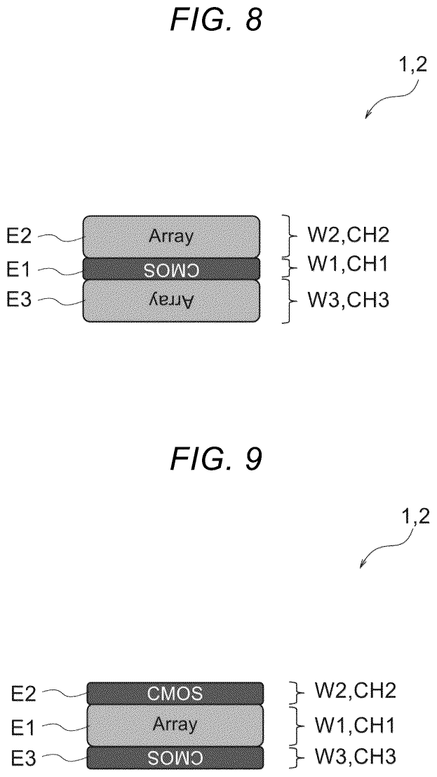

FIG. 10 is a diagram illustrating a configuration of a stacked structure 1 according to a fifth embodiment. The fifth embodiment differs from the first embodiment in that four wafers are stacked. In FIG. 10, the semiconductor substrates are omitted.

The stacked structure 1 further includes a wafer W4.

The wafer W4 is, for example, a logic wafer. The wafer W4 is provided between on one surface (e.g., the surface F11) of the wafer W1 and the wafer W2. The wafer W4 includes a semiconductor element E4 and a semiconductor substrate S4 on which the semiconductor element E4 is provided. In FIG. 10, the semiconductor substrate S4 is omitted.

The wafer W4 is stuck to the wafer W1 on the lower surface of the wafer W4. Similarly, the wafer W4 is stuck to the wafer W2 on the upper surface of the wafer W4.

The wafers W1, W4 are wafers of the same type. That is, the semiconductor elements E1, E4 are elements of the same type.

The wafer W4 is disposed such that the wafer W4 and the wafer W1 face each other. That is, the wafers W1, W4 are disposed upside down with respect to each other. Accordingly, the warpage of the wafers W1, W4 can be canceled. As a result, the warpage of the stacked structure 1 and the semiconductor device 2 can be prevented.

It should be noted that both the wafers W1, W4 may be inverted upside down.

The wafers W2, W3 are disposed with the two wafers W1, W4 interposed therebetween. The wafers W2, W3 face each other with the two wafers W1, W4 interposed therebetween. Accordingly, the warpage of the wafers W2, W3 can be canceled. As a result, the warpage of the stacked structure 1 and the semiconductor device 2 can be prevented.

Detailed description of the semiconductor device 2 including the chips CH1, CH2, CH3, CH4 obtained by dividing the wafers W1, W2, W3, W4 is omitted.

In addition, five or more wafers may be stacked. Also in this case, the wafers W2, W3 are disposed with three or more wafers interposed therebetween.

As in the fifth embodiment, four wafers may be stacked. The stacked structure 1 of the fifth embodiment can achieve an effect similar to that of the first embodiment. In addition, the stacked structure 1 according to the fifth embodiment may be combined with the second embodiment. That is, both the wafers W2, W3 may be inverted upside down.

### Sixth Embodiment

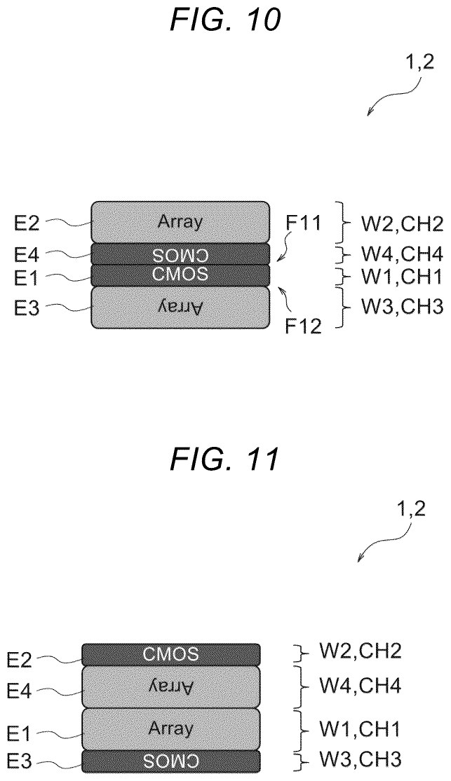

FIG. 11 is a diagram illustrating a configuration of a stacked structure 1 according to a sixth embodiment. The sixth embodiment differs from the fifth embodiment in that two logic wafers are disposed with two memory array wafers interposed therebetween. That is, the sixth embodiment is also a combination of the fourth embodiment and the fifth embodiment. In FIG. 11, the semiconductor substrates are omitted.

The wafer W1, W4 are, for example, memory array wafers. The wafers W2, W3 are, for example, logic wafers.

As in the fifth embodiment, the wafer W4 is disposed such that the wafer W4 and the wafer W1 face each other. Accordingly, the warpage of the wafers W1, W4 can be canceled.

As in the fifth embodiment, the wafers W2, W3 face each other with the two wafers W1, W4 interposed therebetween. Accordingly, the warpage of the wafers W2, W3 can be canceled.

Detailed description of the semiconductor device 2 including the chips CH1, CH2, CH3, CH4 obtained by dividing the wafers W1, W2, W3, W4 is omitted.

As in the sixth embodiment, two logic wafers may be disposed with two memory array wafers interposed therebetween. The stacked structure 1 of the sixth embodiment can achieve an effect similar to that of the fifth embodiment.

In the present embodiment, the wafer W1 is a logic wafer and the wafer W2 and the wafer W3 are memory array wafers as an example, but the configuration is not limited thereto. For example, the combination of the wafer W1, the wafer W2, and the wafer W3 may be any combination of elements formed on wafers, such a logic, a passive element such as a capacitor, a pixel sensor, or a power semiconductor, as long as the warpage of wafers can be reduced. Also in an embodiment using three or more wafers, any combination can be used as long as the warpage of wafers can be reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A stacked structure for a semiconductor device, comprising:
a first wafer including a first substrate and a first semiconductor element on the first substrate and having first and second surfaces between which the first substrate and the first semiconductor element are disposed;
a second wafer including a second substrate and a second semiconductor element on the second substrate and having first and second surfaces between which the second substrate and the second semiconductor element are disposed, wherein
the second substrate extends along the first surface of the second wafer, and
the second wafer is attached to a first surface side of the first wafer such that the second surface of the second wafer is closer to the first surface of the first wafer than the first surface of the second wafer; and
a third wafer including a third substrate and a third semiconductor element on the third substrate and having first and second surfaces between which the third substrate and the third semiconductor element are disposed, wherein
the third substrate extends along the first surface of the third wafer, and
the third wafer is attached to a second surface side of the first wafer such that the second surface of the third wafer is closer to the second surface of the second wafer than the first surface of the third wafer, wherein
the second and third semiconductor elements are of a same type.

2. The stacked structure according to claim 1, further comprising:
a fourth wafer including a fourth semiconductor element and sandwiched between the first and second wafers.

3. The stacked structure according to claim 2, wherein
the second and third semiconductor elements are of a same type, and
the first and fourth semiconductor elements are of a same type.

4. The stacked structure according to claim 3, wherein
each of the second and third semiconductor elements includes a memory cell array, and
each of the first and fourth semiconductor elements includes a CMOS control circuit configured to control the memory cell array.

5. The stacked structure according to claim 1, wherein
each of the second and third semiconductor elements includes a memory cell array, and
the first semiconductor element includes a CMOS control circuit configured to control the memory cell array.

6. The stacked structure according to claim 1, wherein
a thickness of the second substrate differs from a thickness of the third substrate.

7. The stacked structure according to claim 6, wherein
a thickness of the first substrate is less than the thickness of one of the second and third substrates.

8. The stacked structure according to claim 6, wherein
a thickness of the first substrate is less than the thickness of both the second and third substrates.

9. The stacked structure according to claim 1, wherein
the first substrate of the first wafer extends along the second surface of the first wafer.

10. A semiconductor device comprising:
a first chip including a first substrate and a first semiconductor element on the first substrate and having first and second surfaces between which the first substrate and the first semiconductor element are disposed;
a second chip including a second substrate and a second semiconductor element on the second substrate and having first and second surfaces between which the second substrate and the second semiconductor element are disposed, wherein
the second substrate extends along the first surface of the second chip, and
the second chip is attached to a first surface side of the first chip such that the second surface of the second chip is closer to the first surface of the first chip than the first surface of the second chip; and
a third chip including a third substrate and a third semiconductor element on the third substrate and having first and second surfaces between which the third substrate and the third semiconductor element are disposed, wherein
the third substrate extends along the first surface of the third chip, and
the third chip is attached to a second surface side of the first chip such that the second surface of the third chip is closer to the second surface of the second chip than the first surface of the third chip, wherein
the second and third semiconductor elements are of a same type.

11. The semiconductor device according to claim 10, further comprising:
a fourth chip including a fourth semiconductor element sandwiched between the first and second chips.

12. The semiconductor device according to claim 11, wherein
the second and third semiconductor elements are of a same type, and
the first and fourth semiconductor elements are of a same type.

13. The semiconductor device according to claim 12, wherein
each of the second and third semiconductor elements includes a memory cell array, and
each of the first and fourth semiconductor elements includes a CMOS control circuit configured to control the memory cell array.

14. The semiconductor device according to claim 10, wherein
each of the second and third semiconductor elements includes a memory cell array, and
the first semiconductor element includes a CMOS control circuit configured to control the memory cell array.

15. A method for manufacturing a semiconductor device, the method comprising:
sticking a first wafer that includes a first surface and a first semiconductor element formed along the first surface, to a second wafer that includes a second surface and a second semiconductor element formed along the second surface such that the first and second surfaces face each other, the first wafer being warped such that the first surface has a convex shape, the second wafer being warped such that the second surface has a convex shape; and
stacking a third wafer including a third surface and a third semiconductor element formed along the third surface, on a first back surface of the first wafer that is opposite to the first surface, the third wafer being warped such that the third surface has a convex shape.

16. The method according to claim 15, further comprising:
removing at least part of the first back surface after the first and second surfaces are stuck together.

17. The method according to claim 15, further comprising:
forming an external connection pad on a side of a second back surface of the second wafer opposite to the second surface, or
forming an external connection pad on a side of a third back surface of the third wafer opposite to the third surface.

18. The method according to claim 17, further comprising:
removing at least part of the second wafer from a side of the second back surface before forming the external connection pad, or
removing at least part of the third wafer from a side of the third back surface before forming the external connection pad.

19. The method according to claim 15, wherein the first semiconductor element is a CMOS control circuit, and the second and third semiconductor elements are memory cell arrays.

20. The method according to claim 15, wherein a degree of warpage of the first wafer is smaller than a degree of warpage of the second wafer.
